(19) United States
(12) Patent Application Publication
(10) Pub. No.: US 2006/0220016 A1
(43) Pub. Date: Oct. 5, 2006

(54) Light emitting display and method of manufacturing the same

(76) Inventors: Su Mi Lee, Suwon (KR); Kwan Hee Lee, Seoul (KR)

Correspondence Address: CHRISTIE, PARKER & HALE, LLP, PO BOX 7068, PASADENA, CA, 91109-7068, US

(21) Appl. No.: 11/378,729

(22) Filed: Mar. 16, 2006

(30) Foreign Application Priority Data
Mar. 21, 2005 (KR) 10-2005-0023198

(51) Int. Cl. H01L 29/04

(52) U.S. Cl. 257/59

(57) ABSTRACT

A light emitting display includes a thin film transistor formed on a substrate, a first insulating layer deposited on the thin film transistor, and at least one organic light emitting diode for forming an image displaying part on the first insulating layer. At least one blocking part is adjacent to at least one side of the image displaying part to substantially prevent foreign matter from flowing to the organic light emitting diode. A method of manufacturing a light emitting display includes preparing a substrate, and forming a thin film transistor, a first insulating layer, a contact hole in the first insulating layer, an image displaying part, at least one blocking part adjacent to a side of the image displaying part, and a pixel electrode.

### CROSS-REFERENCE TO RELATED APPLICATIONS

This application claims priority to and the benefit of Korean Patent Application No. 10-2005-0023198, filed on Mar. 21, 2005, in the Korean Intellectual Property Office, the entire content of which is incorporated herein by reference.

### BACKGROUND

1. Field of the Invention

The present invention relates to a light emitting display and a method of manufacturing the same, and more particularly to, a light emitting display capable of preventing foreign matter such as water, oxygen, and so on from flowing to a light emitting diode through a first insulation layer of the light emitting display, and to a method of manufacturing the same.

2. Discussion of Related Art

Like a cathode ray tube (CRT), a conventional light emitting display has a higher response speed than a passive light emitting diode, such as a crystal liquid display (LCD), which requires an independent light source.

The light emitting displays in flat panel displays (FPDs) can provide vivid motion pictures because of a wider range of operating temperatures, more durability against shock or vibration, a wider viewing angle, and a higher response speed relative to other FPDs. Light emitting displays, in view of material and structure, are divided into inorganic light emitting displays, including an inorganic light emission layer, and an organic light emitting display, including an organic light emission layer. Organic light emitting displays generate light by electrons and holes making electron-hole couples in a semiconductor. Carriers are excited to a higher energy level and, after excitation, are dropped to the ground state.

Hereinafter, conventional light emitting displays will be described in detail with reference to the accompanying drawings.

FIG. 1 is a plan view schematically illustrating a conventional light emitting display, and FIG. 2 is a side sectional view taken along the line II-II′ in FIG. 1. As shown in FIG. 1, a conventional light emitting display 100 includes a substrate 110, an image displaying part 111 having an organic light emitting diode (OLED) (not shown), a pad part 112 having a plurality of pads formed in a side of the substrate 110, a power source line 115 formed along the rim of the substrate 110 except for a region where the pad part 112 is formed, a scan driver 113, and a data driver 114.

More particularly, referring to FIG. 2, the conventional light emitting display 100 includes a buffer layer 120, semiconductor layers 130, 131, and 132, a gate insulating layer 125, an interlayer insulating layer 135, source and drain electrodes 141 and 142, a first insulating layer 145, an OLED 150, and a transmissive panel 155 sequentially formed on the substrate 110.

First, the buffer layer 120 including oxide film is formed on the substrate 110, and the semiconductor layers 130, 131, and 132 are formed on the buffer layer 120 by forming and patterning a poly-silicon layer. The gate insulating layer 125 is formed on the buffer layer 120 including the semiconductor layers 130, 131, and 132, a gate metal layer is deposited on the gate insulating layer 125, and the gate electrode 140 is formed by patterning the deposited gate metal layer.

Interlayer insulating layer 135 is formed on the gate electrode 140, and the source and drain electrodes 141 and 142 are formed by depositing and patterning the source/drain metal layers. Generally, a data line (not shown) and the power source line 115 are formed simultaneously with the source electrode 141 and the drain electrode 142. On the interlayer insulating layer 135 on which the source electrode 141, the drain electrode 142, and the power source line 115 are formed, in order to remove pattern flexion due to the patterns such as the source electrode, the drain electrode, and the power source line, the first insulating layer 145 is formed, and the OLED 150, generally having colors of red (R), green (G), and blue (B), is formed on the first insulating layer 145.

Moreover, above the first insulating layer 145 on which the OLED 150 is formed, the transmissive panel 155 for covering the OLED is provided to prevent the upper region from being exposed. On the lower surface of the transmissive panel 155, i.e. on a surface facing the upper region of the OLED 145, a transmissive humidity absorbing agent 156 is formed. The transmissive panel 155 and the first insulating layer 145 are bonded to each other by a sealant 160 coated on a surface thereof along the circumference.

However, in the conventional light emitting display, the first insulating layer, formed to remove stepped portions due to the pattern flexion of every layer, is generally made of silicon or benzocyclobutene (BCB), acrylic, polyimide, and so on, and since the adhesion of these materials is relatively weak due to their characteristics, the adhesion between the first insulating layer and the transmissive panel may be deteriorated when coating the sealant to a surface of the first insulating layer or the transmissive panel and bonding the first insulating layer to the transmissive panel. Thus, at high temperature and humidity, moisture or oxygen may permeate into the light emitting display from the outside.

Moreover, in the conventional light emitting display, when moisture permeates the light emitting display, the permeated moisture may directly contact the OLED along the first insulating layer so that luminous efficiency of the OLED is deteriorated and life span thereof is reduced.

### SUMMARY OF THE INVENTION

Accordingly, a light emitting display may include a blocking part for blocking foreign matter from flowing from the outside to a first insulating layer such that the foreign matter containing moisture does not directly contact an organic light emitting diode (OLED). A method of manufacturing this display is also described below.

A light emitting display may also include an inorganic insulating layer formed on a first insulating layer to enhance adhesion between the first insulating layer formed to reduce the stepped portions of patterns and a transmissive panel formed above an OLED. A method of manufacturing this display is also described below.

The foregoing and/or other aspects of the present invention are achieved by providing a light emitting display including a thin film transistor formed on a substrate, a first insulating layer deposited on the thin film transistor, and at least one OLED for forming an image displaying part on the first insulating layer. A blocking part is formed adjacent to at least one side of the image displaying part to prevent foreign matter from flowing to the OLED.

In one embodiment, the light emitting display further includes an inorganic insulating layer formed on the first insulating layer before forming the pixel electrode. The blocking part can be a slot-shaped through-hole penetrating the first insulating layer, and the through-hole may be formed in the first insulating layer and the inorganic insulating layer to have a width of at least 2 μm. In one embodiment, the inorganic insulating layer is selected from SiNx and SiOx.

The height of the blocking part can equal the width of the first insulating layer or be greater or less than the thickness of the first insulating layer.

In another embodiment, a light emitting display includes a thin film transistor formed on a substrate, a first insulating layer above the thin film transistor, an inorganic insulating layer formed on the first insulating layer, and at least one OLED forming an image displaying part on the inorganic insulating layer. At least one blocking part is formed in the first insulating layer along the outer circumference of an image displaying region formed by the OLED to substantially prevent foreign matter from flowing to the OLED.

Still another embodiment of a method of manufacturing a light emitting display includes preparing a substrate, forming a thin film transistor including source and drain electrodes on the substrate, forming a first insulating layer on the thin film transistor, forming a contact hole in the first insulating layer, forming at least one blocking part in at least one side of an image displaying part including at least one OLED driven by the thin film transistor, and forming a pixel electrode formed on the first insulating layer and electrically connected to the source electrode or the drain electrode via the contact hole.

In one embodiment, the method further includes forming an inorganic insulating layer on the first insulating layer before forming the pixel electrode. The blocking part may be formed simultaneously with forming the contact hole. The blocking part may be formed separately from forming the contact hole.

### BRIEF DESCRIPTION OF THE DRAWINGS

These and/or other aspects and features of the invention will become apparent and more readily appreciated from the following description of examples of embodiments, taken in conjunction with the accompanying drawings of which:

FIG. 1 is a plan view schematically illustrating a conventional light emitting display;

FIG. 2 a side sectional view taken along the line II-II′ in FIG. 1;

FIG. 3 is a plan view illustrating a light emitting display according to an embodiment of the present invention;

FIG. 4 is a side sectional view taken along the line IV-IV′ in FIG. 3;

FIG. 5 is a side sectional view illustrating a light emitting display according to another embodiment of the present invention;

FIGS. 6A to 6E are side sectional views illustrating steps for the manufacture of the light emitting display shown in FIG. 3;

FIGS. 7A to 7C are side sectional views illustrating steps for the manufacture of a light emitting display according to yet another embodiment of the present invention;

FIG. 8 is a plan view illustrating a light emitting display according to another embodiment of the present invention;

FIG. 9 is a side sectional view taken along the line IX-IX′ in FIG. 8; and

FIG. 10 is a side sectional view illustrating a light emitting display according to another embodiment of the present invention.

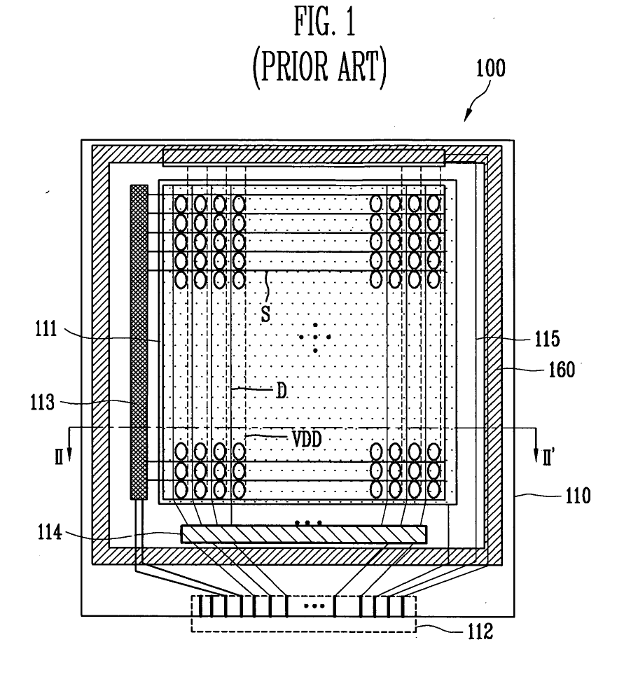

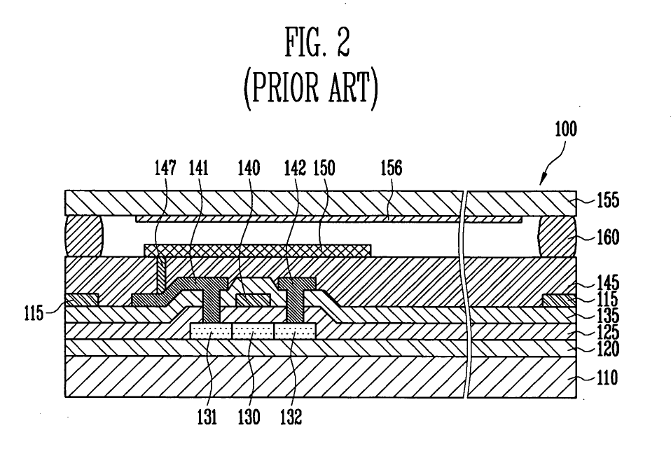

### DETAILED DESCRIPTION

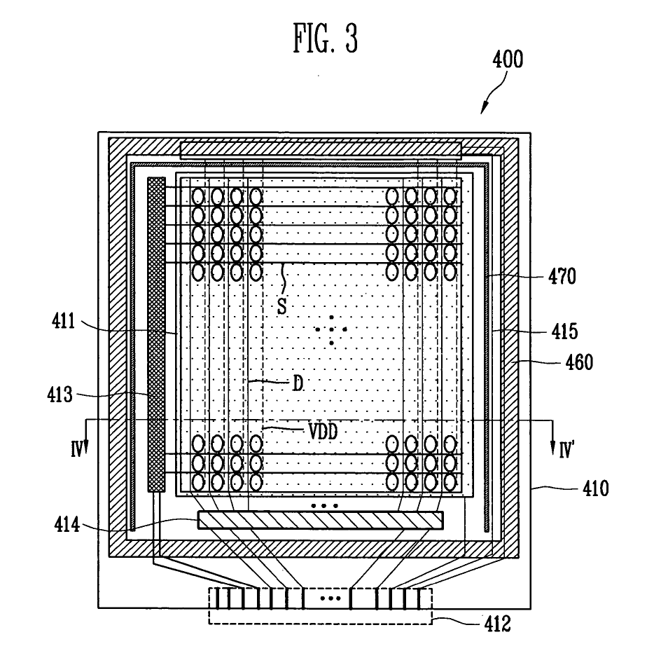

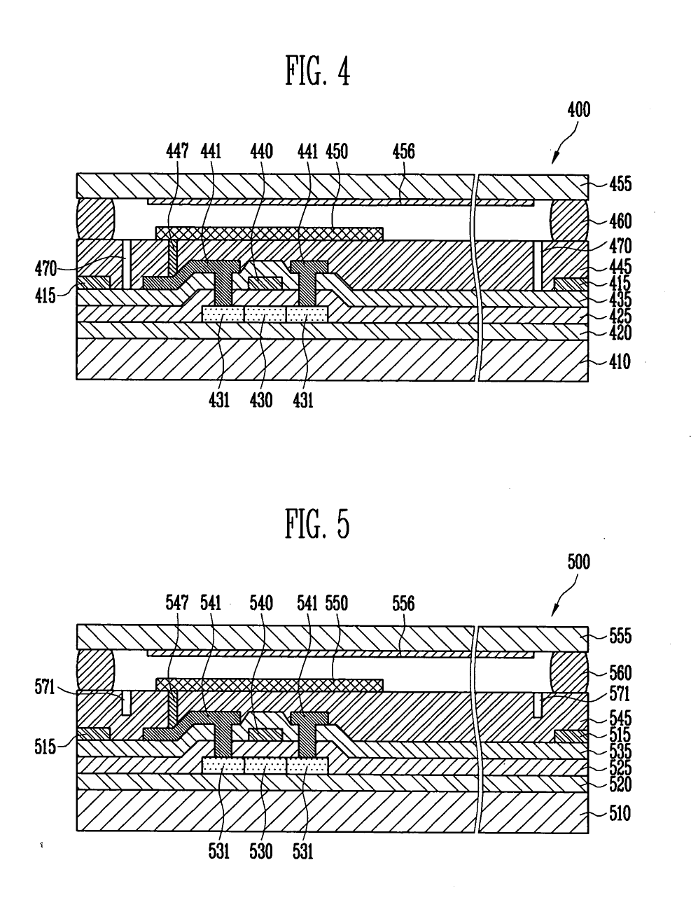

Hereinafter, examples of embodiments according to the present invention will be described with reference to the accompanying drawings. FIG. 3 is a plan view illustrating a light emitting display according to an embodiment of the present invention, FIG. 4 is a side sectional view taken along the line IV-IV′ in FIG. 3, and FIG. 5 is a side sectional view illustrating a light emitting display according to another embodiment of the present invention. Here, like reference numerals refer to like elements throughout to avoid duplicated description.

As shown in FIG. 3, a light emitting display 400 includes a substrate 410, an image displaying part 411 having at least one sub-pixel driven by at least one thin film transistor (not shown) formed in a crossing region of scanning lines S and data lines D formed on the substrate 410, a pad part 412 formed at a side of the substrate 410, a power source line 415 formed on the substrate 410 except for the pad part 412, a scanning driver 413 formed between the image displaying part 411 and the power source 415, and a data driver 414 formed between the image displaying part 411 and the pad part 412.

As shown in FIGS. 3-5, the light emitting display 400, 500 includes a buffer layer 420, 520 formed on the substrate 410, 510, semiconductor layers 430, 530 and 431, 531, a gate insulating layer 425, 525, a gate electrode 440, 540, an interlayer insulating layer 435, 535, source and drain electrodes 441, 541, and an OLED 450, 550.

The buffer layer 420, 520 is formed on the substrate 410, 510 and the semiconductor layers 430, 530 and 431, 531 are formed on the buffer layer 420, 520 and include source and drain regions 431, 531. The gate insulating layer 425, 525 is formed on the substrate 410, 510 on which the semiconductor layers 430, 530 and 431, 531 are formed, and the gate electrode 440, 540 is formed on the gate insulating layer 425, 525.

The interlayer insulating layer 435, 535 is formed on the gate insulating layer 425, 525 and includes a first contact hole (not shown) for exposing the source and drain regions 431, 531. The source and drain electrodes 441, 541 contacting the source and drain regions 431, 531 via the first contact hole are formed on the interlayer insulating layer 435, 535. Generally, the power source line 415, 515 is formed simultaneously with the source and drain electrodes 441, 541.

The first insulating layer 445, 545 is formed on the interlayer insulating layer 435, 535 on which the source and drain electrodes 441, 541 and the power source line 415, 515 are formed so that the pattern flexion due to the patterns of the source and drain electrodes 441, 541 and the power source line 415, 515 can be reduced. On the first insulating layer 445, 545, a second contact hole 447, 547 for exposing one of the source and drain electrodes 441, 541 is formed. The OLED 450, 550 is formed on the first insulating layer 445, 545, and generally has three colors such as red (R), green (G), and blue (B). A pixel electrode (not shown) for forming the OLED 450, 550 is connected to the source and drain electrodes 441, 541 via the second contact hole 447, 547 formed on the first insulating layer 445, 545.

In the first insulating layer 445, 545, in order to prevent foreign matter from flowing to the OLED 450, 550 through the first insulating layer 445, 545, a blocking part 470 (FIG. 4) or 571 (FIG. 5) is on one or more sides of the image displaying part 411 of the image display device, on which an image is displayed by the OLED 450, 550 and the thin film transistor. The blocking part 470 (or 571) is formed at the insides of the power source line 415, 515 and the pad part 412 along the circumferences of the image displaying part 411, the scanning driver 413, 513, and the data driver 414, 514.

The blocking part 470 shown in FIG. 4 is a through-hole formed over the deposition thickness of the first insulating layer 445, i.e. the entire thickness of the first insulating layer 445, by etching and may be formed when the second contact hole 447 is formed. The width of the blocking part 470 is, in one embodiment, 2 μm to 50 μm, and may be designed within the range allowed in the designing process by considering the arrangement of other elements of the light emitting display.

The blocking part 571 shown in FIG. 5 may be formed as a recess having a thickness thinner than the deposition thickness of the first insulating layer 545. The recess-shaped blocking part 571 may be formed using a separate mask or by a half tone process. The recess-shaped blocking part 571 may also be formed simultaneously with the second contact hole 547 or separately, and its etching width is, in one embodiment, more than 2 μm.

Referring again to FIGS. 4 and 5, above the first insulating layer 445, 545 on which the OLED 450, 550 is formed, a transmissive panel 455, 555 is formed for covering the OLED 450, 550 such that the upper region of the OLED 450, 550 is not exposed to the outside. On the lower side of the transmissive panel 455, 555, that is, on a surface facing the upper region of the OLED 445, 545, a transmissive humidity absorbing agent 456, 556 is formed. The transmissive panel 455, 555 and the first insulating layer 445, 545 are bonded by sealant coated along at least one side along the periphery of the transmissive panel 455, 555 and the first insulating layer 445, 545.

By the structures as shown in FIGS. 3 to 5, the foreign matter does not contact the OLED 450, 550 directly since, although foreign matter including moisture permeates through the first insulating layer 445, 545, the foreign matter is guided along the blocking part 470, 571. Additionally, the moisture flowing to the first insulating layer 445, 545 and guided along the blocking part 470, 571 can be removed by the humidity absorbing agent 456, 556 formed at the lower region of the transmissive panel 455, 555.

Although, in the above embodiment, the blocking part 470, 571 is formed prior to forming the first insulating layer 445, 545 and the OLED 450, 550, the blocking part 470, 571 may be formed after forming the OLED 450, 550 on the first insulating layer 445, 545. Moreover, in FIGS. 4 and 5, a gap between the OLED 450, 550 and the transmissive panel 455, 555 is shown to be relatively wide for illustrative purposes.

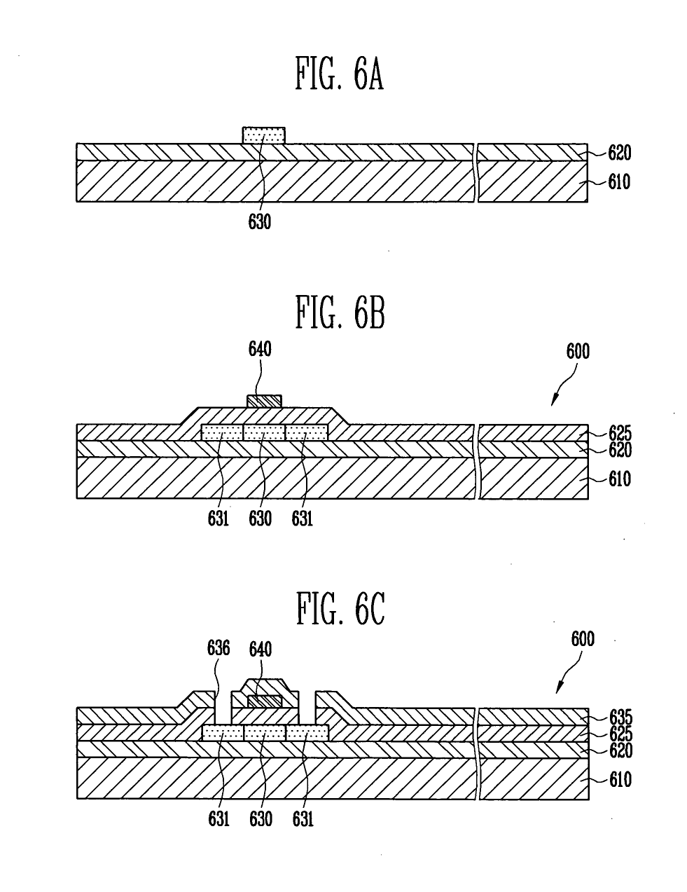

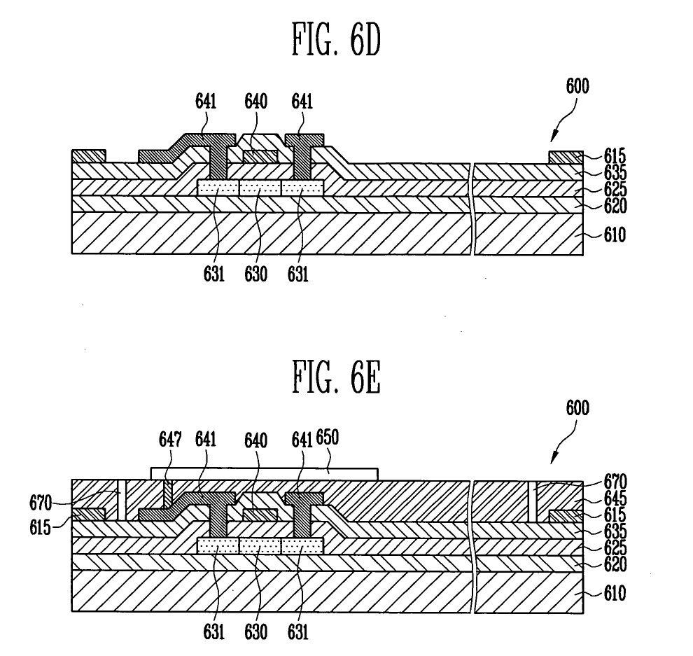

FIGS. 6A to 6E are side sectional views illustrating steps in the manufacture of a light emitting display according to the embodiment shown in FIGS. 3 and 4.

First, as shown in FIGS. 6A and 6B, in order to manufacture a light emitting display 600, a substrate 610 is provided, and a buffer layer 620 and semiconductor layers 630 and 631 are formed on the substrate 610. Generally, the substrate 610 is made of glass substrate or an insulating substrate such as synthetic resin, and the semiconductor layers 630 and 631 are formed by depositing and patterning amorphous silicon.

As shown in FIG. 6B, a gate insulating layer 625 is formed on the buffer layer 620 containing the semiconductor layers 630 and 631, and a gate electrode 640 is formed on the gate insulating layer 625 by depositing and patterning gate metal. Next, n-type or p-type impurities are injected into the semiconductor layers by ion implantation such that source and drain portions 631 are formed on the semiconductor layers.

Next, as shown in FIG. 6C, on the substrate 610 on which the source and drain portions 631 are formed, an interlayer insulating layer 635 is formed by deposition method, such as Plasma-Enhanced Chemical Vapor Deposition (PECVD), and a first contact hole 636 is formed for connecting source and drain electrodes 641 in the next step. The first contact hole 636 is formed by etching the interlayer insulating layer 635.

As shown in FIG. 6D, by patterning source and drain metal deposited on the interlayer insulating layer 635, the source and drain electrodes 641 are formed on the interlayer insulating layer 635 at the same time as the power source line 615 is formed. The source and drain electrodes 641 respectively contact the source and drain portions 631 through the first contact hole 636.

Next, as shown in FIG. 6E, in order to mitigate the pattern flexion of the source and drain electrodes 641, the first insulating layer 645 is formed on the interlayer insulating layer 635. On the first insulating layer 645, a second contact hole 647 for electrically connecting the source and drain electrode 641 with an OLED 650, that will be formed in the following step, is formed. In the first insulating layer 645, in order to prevent foreign matter from flowing to the OLED 650, a blocking part 670 is formed at any position along the outer circumference of the image displaying part formed by the OLED 650 over a thickness of the first insulating layer 645. The second contact hole 647 and the blocking part 670 may be formed simultaneously or separately.

The blocking part 670 is a slot-shaped through-hole formed by once-performed etching and extending to the deposition thickness of the first insulating layer 645. The width of a through-hole 681 is, in one embodiment, 2 μm to 50 μm, and may be formed within the range allowed in a designing process by considering the arrangement of other elements of the light emitting display. Although, in this embodiment, the hole-shaped blocking part is formed over the entire thickness of the first insulating layer 645, the blocking part 670 may be also formed in the form of a recess. The recess-shaped blocking part 670 may be formed using a separate mask or a half tone process.

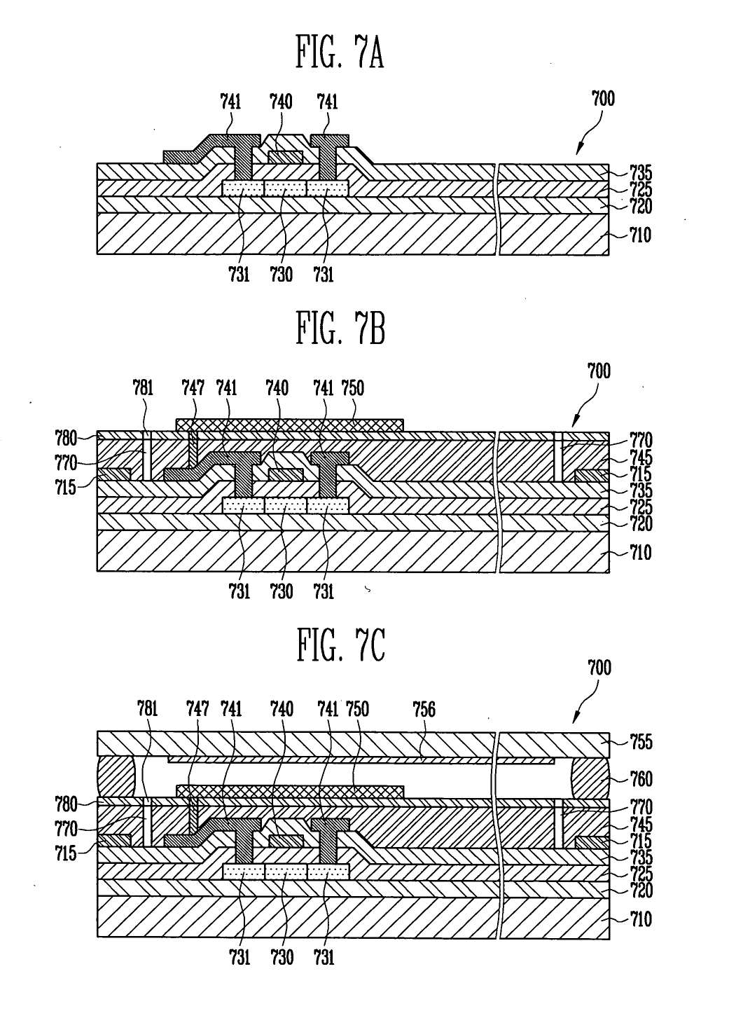

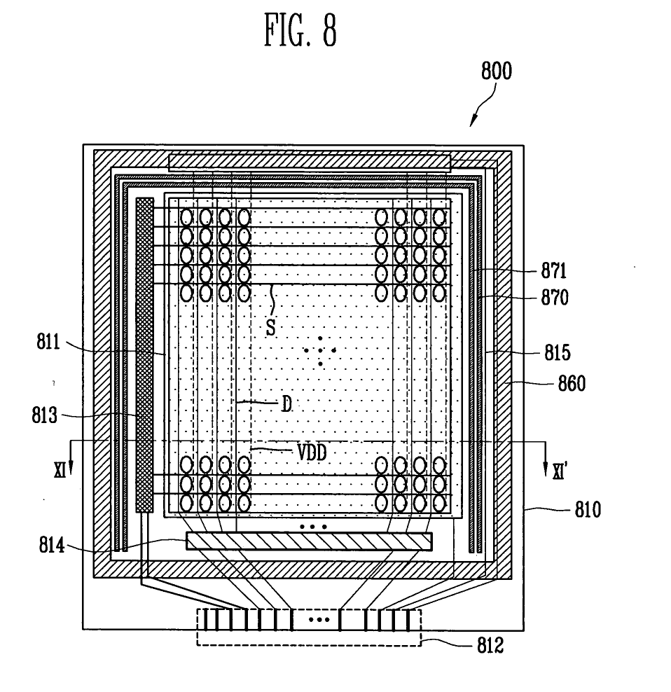

FIGS. 7A to 7C are side sectional views illustrating steps for manufacturing a light emitting display according to another embodiment of the present invention. In the manufacturing process shown in FIGS. 7A to 7C, drawings illustrating the same processes as those shown in FIGS. 6A to 6E are omitted and description thereof are also omitted for the illustrative convenience. Moreover, like reference numerals refer to like elements depicted and described in relation to in FIGS. 6A to 6E.

The process of forming a thin film transistor that forms the light emitting display according to this embodiment of the present invention will be described with reference to FIGS. 7A to 7C. As shown in FIG. 7A, a thin film transistor of a light emitting display 700 includes semiconductor layers 730 and 731, a gate insulating layer 725 formed on a buffer layer 720, a gate electrode 740, an interlayer insulating layer 735, and source and drain electrodes 741.

As shown in FIG. 7B, a power source line 715 is formed on the interlayer insulating layer 735, a first insulating layer 745 is formed on a substrate 710, and an inorganic insulating layer 780 is formed on the first insulating layer 745. A blocking part for preventing foreign matter from flowing to an OLED 750 via the first insulating layer 745 is formed in the first insulating layer 745 and the inorganic insulating layer 780. The blocking part 770 is a through-hole extended over the thicknesses of the first insulating layer 745 and the inorganic insulating layer 780. The hole-shaped blocking part 770 may be formed simultaneously with the second contact hole or separately by etching.

Moreover, in this embodiment, although the blocking parts 770 and 781 are formed after laminating all the first insulating layer 745 and the inorganic insulating layer 780, after forming the blocking part 770 in the first insulating layer 745 and laminating the inorganic insulating layer 780, the blocking part 781, connected to the blocking part 770, may be formed in the laminated inorganic insulating layer 780. In this embodiment, the blocking part 781 is also a through-hole formed by etching. The blocking parts 770 and 781 may be formed simultaneously with the second contact hole 747 or separately.

The first insulating layer 745 is made of thermosetting resin, such as acrylic resin, BCB, and the like, and flat, and performs the functions of an insulating layer and a protecting layer. Here, the inorganic insulating layer 780 is made of one of SiNx and SiOx, and is deposited to a thickness of 200 Å to 500 Å (1 Å=10⁻¹⁰ m) . After forming the inorganic insulating layer 780, the OLED 750 is electrically connected to the second contact hole 747 formed in the first insulating layer 745 and the inorganic insulating layer 780.

Next, as shown in FIG. 7C, a transmissive panel 755 enclosing the upper portion of the OLED 750 is formed on the inorganic insulating layer 780. A transparent humidity absorbing agent 756 for absorbing humidity and transmitting light generated from the OLED 750 is formed on the lower surface of the transmissive panel 755, i.e., on the surface facing the upper side of the OLED 750. The transmissive panel 755 and the inorganic insulating layer 780 are bonded by sealant 760 coated on a side of at least one of the transmissive panel 755 and the inorganic insulating layer 780 along the circumference.

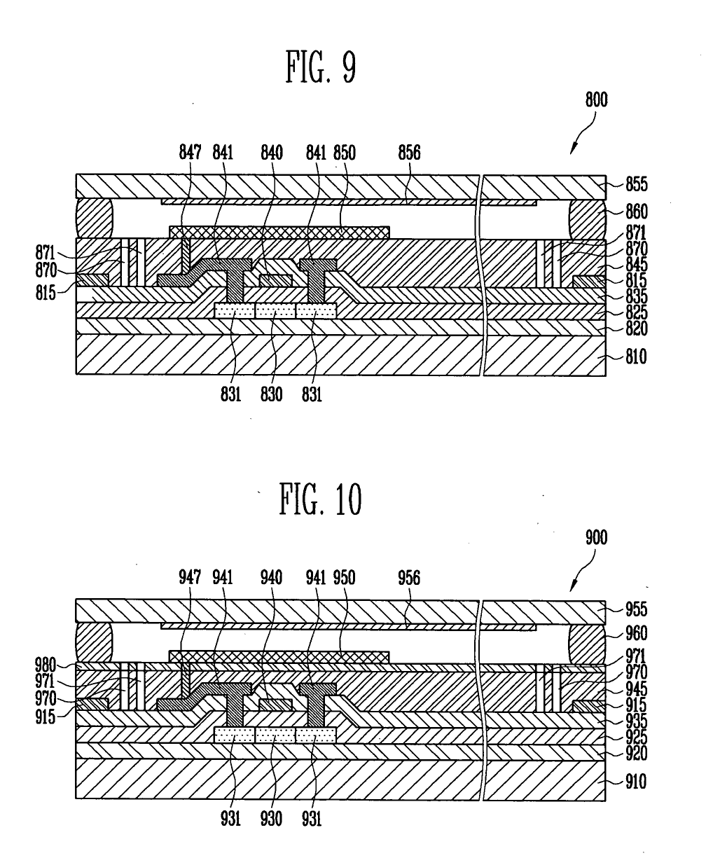

FIG. 8 is a plan view illustrating a light emitting display according to another embodiment of the present invention, and FIG. 9 is a side sectional view taken along the line IX-IX′ in FIG. 8. To avoid duplicated description, description of elements like the elements in FIGS. 3 to 5 will be omitted.

As shown in FIG. 8, a light emitting display 800 includes a substrate 810, an image displaying part 811 formed by an OLED, a pad part 812, a power source line 815, a scanning driver 813, and a data driver 814. As shown in FIGS. 8 and 9, the light emitting display 800 further includes a buffer layer 820 formed on the substrate 810, semiconductor layers 830 and 831, a gate insulating layer 825, a gate electrode 840, an interlayer insulating layer 835, source and drain electrodes 841, a first insulating layer 845, and an OLED 850.

In this embodiment, the first insulating layer 845 is formed on the source and drain electrodes 841 to reduce pattern flexion by the source and drain electrodes 841 and the power source line 815. The source and drain electrodes 841 and the power source line 815 are formed on the interlayer insulating layer 835.

A second contact hole 847 for exposing any one of the source and drain electrodes 841 is formed in the first insulating layer 845. The OLED 850 is formed on the first insulating layer 845 and generally has colors, such as red (R), green (G), and blue (B). A pixel electrode (not shown) serving to as an element of the OLED 850 is electrically connected to the source and drain electrodes 841 via the second contact hole 847 formed on the first insulating layer 845.

In the first insulating layer 845, in order to prevent foreign matter from flowing to the OLED 850 via the first insulating layer 845, a pair of blocking parts 870 and 871 is formed along the circumference of the image displaying part 811. The blocking parts 870 and 871 are spaced apart from each other to form two lines within the power source line 815 and the pad part 812 along the circumferences of the image displaying part 811, the scanning driver 813, and the data driver 814.

Each of the blocking parts 870 and 871 shown in FIG. 9 are through-holes formed by etching over the deposit thickness of the first insulating layer 845, and may be formed simultaneously when the second contact hole 847 is formed. The width of the blocking parts is, in one embodiment, 2 μm to 50 μm. The blocking parts are formed based on the designing process by considering the arrangement of other elements of the light emitting display.

Although all the blocking parts 870 and 871, as shown in FIGS. 8 and 9, are formed in the form of through-holes penetrating the first insulating layer 845, one of the blocking parts 870 and 871 may be a through-hole and the other may be recess, or both of them may be through-holes. When at least one of the blocking parts 870 and 871 is formed in the form of a recess, a separate mask or a half tone process may be used. Moreover, when forming the blocking parts in the form of a recess, the blocking parts may be formed simultaneously with the second contact hole 847 or separately, and the width thereof is, in one embodiment, 2 μm to 50 μm. Above the first insulating layer 845 on which the OLED 850 is formed, in order to prevent the OLED 850 from being exposed to the outside, a transmissive panel 855 is formed. A humidity absorbing agent 856 is formed on the lower surface of the transmissive panel 855.

FIG. 10 is a side sectional view illustrating a light emitting display according to another embodiment of the present invention. For illustrative purposes, detailed description of elements like the elements in FIGS. 7A-7C will be omitted and the description of the light emitting display will focus on the characteristic structure of this embodiment.

As shown in FIG. 10, the light emitting display 900 includes a buffer layer 920 formed on a substrate 910, semiconductor layers 930 and 931, a gate insulating layer 925, a gate electrode 940, an interlayer insulating layer 935, source and drain electrodes 941, a first insulating layer 945, an inorganic insulating layer 980, an OLED 950, and a transmissive panel 955 on which a humidity absorbing agent 956 is formed.

In this embodiment, the first insulating layer 945 is formed on the substrate 910 on which thin film transistors including the semiconductor layers 930 and 931, the gate electrode 940, and the source and drain electrodes 941 are formed, and a pair of blocking parts 970 and 971 for blocking foreign matter, which would be introduced via the first insulating layer 945, is formed in the first insulating layer 945 and the inorganic insulating layer 980.

The blocking parts 970 and 971 are through-holes formed by etching and extend over the thicknesses of the first insulating layer 945 and the inorganic insulating layer 980. The hole-shaped blocking parts 970 and 971 may be formed simultaneously with a contact hole 947 or separately, and the width of the blocking parts 970 and 971 is, in one embodiment, 2 μm to 50 μm or within a range allowed in the designing process by considering the arrangement of other elements. The blocking parts 970 and 971 shown in FIG. 10 may be through-holes like the blocking parts 870 and 871 in FIGS. 8 and 9, one of them may be a through-hole and the other may be a recess, or both of them may be a through-hole.

In the light emitting displays 800 and 900 according to the embodiments shown in FIGS. 8 to 10, since foreign matter containing moisture flows from the outside through the first insulating layers 845 and 945 of the respective light emitting displays 800 and 900 and is guided by the blocking parts 870, 871, 970, and 971, it is possible to prevent the foreign matter flown through the first insulating layers 845 and 945 from directly contacting the OLEDs 850 and 950.

In the above-mentioned embodiments, although the light emitting displays include the first insulating layer in which the blocking parts are formed, or the first insulating layer and the inorganic insulating layer while the blocking parts extend over the first insulating layer and the inorganic insulating layer, the blocking parts may be formed in the first insulating layer and the inorganic insulating layer, respectively.

In the above-mentioned embodiments of the present invention, although the blocking parts are formed in a linear shape and are connected to each other to form a “U”-shape, the blocking parts may be formed in various dotted shapes spaced apart from each other.

The blocking parts in the above examples of embodiments are formed on the first insulating layer so that it is possible to prevent foreign matter from directly contacting the OLED via the first insulating layer. Therefore, it is possible to provide a light emitting display capable of enhancing luminous efficiency and of increasing life span of the OLED and a method of manufacturing the same.

According to these embodiments of the present invention, in order to reduce the pattern flexion, the inorganic insulating layer is formed on the first insulating layer such that adhesion between the first insulating layer and the transmissive panel is enhanced to prevent foreign matter from flowing from the outside to the light emitting display.

Although a few examples of embodiments of the present invention have been shown and described, it would be appreciated by those skilled in the art that modifications might be made in these embodiments without departing from the principles and spirit of the invention, the scope of which is defined in the claims and their equivalents.

What is claimed is:

1. A light emitting display comprising:
a thin film transistor formed on a substrate;
a first insulating layer deposited on the thin film transistor;
at least one organic light emitting diode on the first insulating layer and forming an image displaying part; and
a blocking part adjacent to a side of the image displaying part to substantially prevent foreign matter from flowing to the at least one organic light emitting diode.

2. The light emitting display as claimed in claim 1, wherein the blocking part has a height that is approximately equal to a thickness of the first insulating layer.

3. The light emitting display as claimed in claim 2, wherein the blocking part comprises a through-hole penetrating the first insulating layer.

4. The light emitting display as claimed in claim 1, wherein the blocking part has a height that is less than a thickness of the first insulating layer.

5. The light emitting display as claimed in claim 4, wherein the blocking part comprises a recess formed in the first insulating layer.

6. The light emitting display as claimed in claim 1, wherein the blocking part has a width of 2 μm to 50 μm.

7. A light emitting display comprising:
a thin film transistor formed on a substrate;
a first insulating layer disposed above the thin film transistor;
an inorganic insulating layer formed on the first insulating layer;
at least one organic light emitting diode forming an image displaying part on the inorganic insulating layer; and
at least one blocking part formed in the first insulating layer adjacent to a side of the image displaying part to substantially prevent foreign matter from flowing to the at least one organic light emitting diode.

8. The light emitting display as claimed in claim 7, wherein the blocking part has a height substantially equal to a total thickness of the first insulating layer and the inorganic insulating layer.

9. The light emitting display as claimed in claim 8, wherein the blocking part comprises a through-hole penetrating the inorganic insulating layer and the first insulating layer.

10. The light emitting display as claimed in claim 7, wherein the blocking part has a height less than a total thickness of the inorganic insulating layer and the first insulating layer.

11. The light emitting display as claimed in claim 10, wherein the blocking part comprises a recess formed in the inorganic insulating layer and the first insulating layer.

12. The light emitting display as claimed in claim 7, wherein the inorganic insulating layer comprises SiNx or SiOx.

13. A method of manufacturing a light emitting display, the method comprising:
preparing a substrate;
forming a thin film transistor including a source electrode and a drain electrode on the substrate;
forming a first insulating layer on the thin film transistor;
forming a contact hole in the first insulating layer;
forming an image displaying part, the image displaying part including at least one organic light emitting diode driven by the thin film transistor;
forming at least one blocking part adjacent to a side of the image displaying part; and
forming a pixel electrode on the first insulating layer, the pixel electrode being electrically connected to the source electrode or the drain electrode via the contact hole.

14. The method as claimed in claim 13, further comprising forming an inorganic insulating layer on the first insulating layer before forming the pixel electrode.

15. The method as claimed in claim 14, wherein the blocking part is formed in the first insulating layer and the inorganic insulating layer.

16. The method as claimed in claim 15, wherein the blocking part is etched simultaneously with the first insulating layer and the inorganic insulating layer.

17. The method as claimed in claim 14, wherein the blocking part is formed simultaneously with forming the contact hole.

18. The method as claimed in claim 14, wherein the blocking part is formed separately from forming the contact hole.

19. The method as claimed in claim 13, wherein a height of the blocking part is substantially equal to a thickness of the first insulating layer.

20. The method as claimed in claim 13, wherein a height of the blocking part is less than a thickness of the first insulating layer.
